(19) United States
(12) Patent Application Publication
(10) Pub. No.: US 2025/0226183 A1
(43) Pub. Date: Jul. 10, 2025

(54) PLASMA TREATMENT DEVICE AND ETCHING METHOD

(71) Applicant: Tokyo Electron Limited, Tokyo (JP)

(72) Inventors: Natsumi TORII, Miyagi (JP); Wataru TAKAYAMA, Miyagi (JP); Takayuki SUZUKI, Miyagi (JP); Hiroki KATO, Miyagi (JP)

(73) Assignee: Tokyo Electron Limited, Tokyo (JP)

(21) Appl. No.: 19/093,642

(22) Filed: Mar. 28, 2025

Related U.S. Application Data
(63) Continuation of application No. PCT/JP2023/029158, filed on Aug. 9, 2023.

(30) Foreign Application Priority Data
Sep. 29, 2022 (JP) 2022-156530

(51) Int. Cl. H01J 37/32; H01L 21/3065

(52) U.S. Cl. CPC H01J 37/32183; H01J 37/32642; H01J 2237/24564; H01J 2237/334; H01L 21/3065

(57) ABSTRACT

A plasma processing apparatus is provided. The apparatus comprises: a plasma processing chamber; a substrate support arranged inside the plasma processing chamber, the substrate support including a lower electrode, an electrostatic chuck, and an edge ring disposed to surround a substrate mounted on the electrostatic chuck; an upper electrode arranged on an upper side of the substrate support; a source RF power supply configured to supply source RF power to generate plasma from a gas; a bias power supply configured to supply bias power; a DC power supply configured to apply a negative DC voltage; an RF filter electrically connected between the edge ring and the DC power supply, and including at least one variable passive element; and a controller configured to control the DC power supply and the variable passive element, and configured to control a voltage of the bias power within a permissible range.

### CROSS-REFERENCE TO RELATED APPLICATIONS

This application is a bypass continuation application of International Application No. PCT/JP2023/029158 having an international filing date of Aug. 9, 2023 and designating the United States, the International Application being based upon and claiming the benefit of priority from Japanese Patent Application No. 2022-156530 filed on Sep. 29, 2022, the entire contents of each are incorporated herein by reference.

### TECHNICAL FIELD

The exemplary embodiment of the present disclosure relates to a plasma processing apparatus and an etching method.

### BACKGROUND

Japanese Laid-open Patent Publication No. 2008-227063 discloses a plasma processing apparatus including a mounting table arranged inside a chamber to mount a wafer, and an edge ring positioned to surround the wafer mounted on the mounting table, and performing plasma processing on the wafer. In this plasma processing apparatus, a negative DC voltage is applied to the edge ring which is worn down by plasma exposure. In this manner, Japanese Laid-open Patent Publication No. 2008-227063 eliminates sheath distortion, and aims to make ions incident vertically on the front surface of the wafer.

### SUMMARY

According to the present disclosure, a bias power voltage is appropriately controlled in plasma processing.

Specifically, the present disclosure provides a plasma processing apparatus comprising: a plasma processing chamber; a substrate support arranged inside the plasma processing chamber, the substrate support including a lower electrode, an electrostatic chuck, and an edge ring disposed to surround a substrate mounted on the electrostatic chuck; an upper electrode arranged on an upper side of the substrate support; a source RF power supply configured to supply source RF power to the upper electrode or the lower electrode to generate plasma from a gas inside the plasma processing chamber; a bias power supply configured to supply bias power to the lower electrode; a DC power supply configured to apply a negative DC voltage to the edge ring; an RF filter electrically connected between the edge ring and the DC power supply, and including at least one variable passive element; and a controller configured to control the DC power supply and the variable passive element to adjust an incident angle of ions in the plasma with respect to an edge region of a substrate mounted on the electrostatic chuck, and configured to control a voltage of the bias power within a permissible range.

### BRIEF DESCRIPTION OF THE DRAWINGS

FIG. 1 is a longitudinal sectional view schematically illustrating a configuration of an etching apparatus according to the present embodiment.

FIG. 2 is a diagram illustrating a power system of the etching apparatus according to the present embodiment.

FIG. 3A is a diagram illustrating a change in sheath shape and tilting of the ion incident direction due to edge ring consumption.

FIG. 3B is a diagram illustrating changes in the sheath shape and tilting of the ion incident direction due to edge ring consumption.

FIG. 4A is a diagram illustrating changes in the sheath shape and tilting of the ion incident direction.

FIG. 4B is a diagram illustrating changes in the sheath shape and tilting of the ion incident direction.

FIG. 5 is a diagram illustrating a relationship between a DC voltage from a DC power supply or impedance of a second RF filter and a tilt correction angle.

FIG. 6 is a diagram illustrating a relationship between the DC voltage from the DC power supply or the impedance of the second RF filter and LF Vpp.

FIGS. 7A and 7B are diagrams illustrating a relationship among a thickness of the edge ring, the DC voltage from the DC power supply, the impedance of the second RF filter, and the LF Vpp.

FIG. 8 is a diagram illustrating an example method for adjusting the DC voltage from the DC power supply and the impedance of the second RF filter.

FIG. 9 is a diagram illustrating another example method for adjusting the DC voltage from the DC power supply and the impedance of the second RF filter.

FIG. 10 is a diagram illustrating yet another example method for adjusting the DC voltage from the DC power supply and the impedance of the second RF filter.

FIG. 11 is a longitudinal sectional view illustrating a configuration of a connection portion according to another embodiment.

FIG. 12 is a diagram for describing a sensor for LF Vpp control in the etching apparatus.

FIG. 13 is a diagram illustrating a power system of an etching apparatus according to another embodiment.

FIG. 14 is a longitudinal sectional view illustrating a configuration of a connection portion according to another embodiment.

### DETAILED DESCRIPTION

In the manufacturing process of semiconductor devices, plasma processing, such as etching, is performed on semiconductor wafers (hereinafter, referred to as “wafers”). During plasma processing, plasma is generated by exciting a process gas, and the wafer is processed by the plasma.

The plasma processing is performed using a plasma processing apparatus. The plasma processing apparatus generally includes a chamber, a stage, and a radio frequency (RF) power supply. In one example, the RF power supply includes a source RF power supply and a bias RF power supply. The source RF power supply provides source RF power to generate the plasma from the process gas inside the chamber. The bias RF power supply supplies bias RF power to attract ions to the wafer. The stage is provided inside the chamber. The stage includes a lower electrode and an electrostatic chuck. In one example, an edge ring is arranged on the electrostatic chuck to surround the wafer mounted on the electrostatic chuck. The edge ring is provided to improve uniformity of the plasma processing performed on the wafer.

Over time during plasma processing, the edge ring is gradually worn down, and its thickness decreases. When the thickness of the edge ring decreases, the sheath shape changes above the edge ring and the edge region of the wafer. When the sheath shape changes, the ion incidence angle in the wafer's edge region tilts away from the vertical. As a result, a recessed feature formed in the edge region of the wafer is tilted with respect to a thickness direction of the wafer.

In order to form a recessed feature extending in the thickness direction of the wafer in the edge region of the wafer, it is necessary to adjust the tilt of the ion incidence angle by controlling a sheath shape above the edge ring and the wafer's edge region. Therefore, in order to control the sheath shape above the edge ring and the edge region of the wafer, for example, Japanese Laid-open Patent Publication No. 2008-227063 proposes a plasma processing apparatus configured to apply a negative DC voltage to the edge ring from a DC power supply.

However, upon thorough examination, the inventor found that increasing the DC voltage to adjust the tilt of the ion incidence angle also increases the Vpp voltage of the bias RF power. However, conventionally, although the RF power is adjusted as a method for adjusting the voltage Vpp, the adjustment of the RF power may have an influence on heat input to the wafer, or may have an influence on process performance.

According to the technology of the present disclosure, the voltage of the bias power is appropriately controlled during plasma processing.

Hereinafter, an etching apparatus serving as the plasma processing apparatus and an etching method according to the present embodiment will be described with reference to the drawings. In addition, in the present specification and the drawings, the same reference numerals will be assigned to elements having substantially the same functional configurations, and thus, repeated description thereof will be omitted.

### <Etching Apparatus>

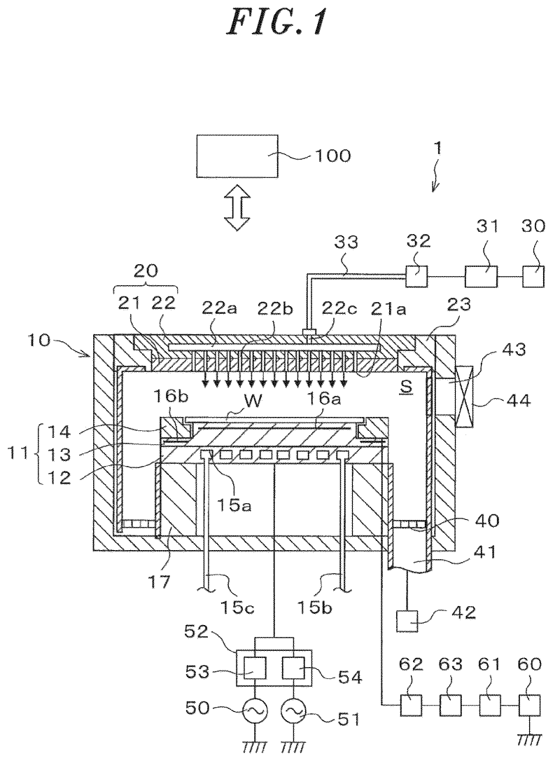

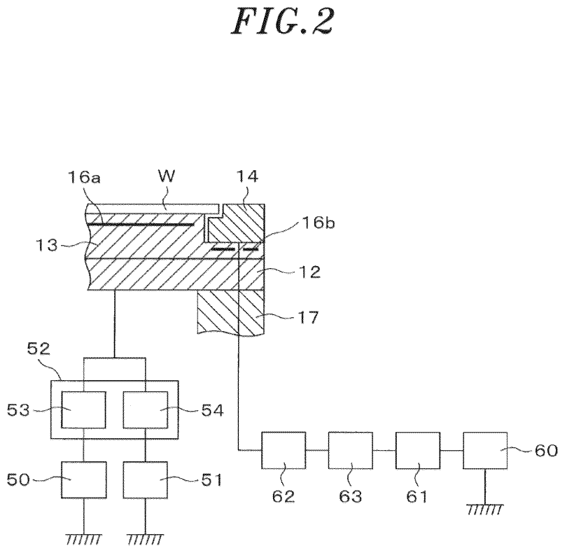

First, the etching apparatus according to the present embodiment is described. FIG. 1 is a longitudinal sectional view schematically illustrating the configuration of an etching apparatus 1. FIG. 2 is a diagram illustrating the power supply system of the etching apparatus 1. The etching apparatus 1 is a capacitively coupled etching apparatus. In the etching apparatus 1, etching is performed on a wafer W, which serves as the substrate.

As illustrated in FIG. 1, the etching apparatus 1 includes a plasma processing chamber 10 having a substantially cylindrical shape. The plasma processing chamber 10 defines the boundary of a processing space S in which the plasma is generated. The plasma processing chamber 10 is made of aluminum, for example. The plasma processing chamber 10 is grounded.

A stage 11, which serves as a substrate support for mounting the wafer W, is accommodated inside the plasma processing chamber 10. The stage 11 includes a lower electrode 12, an electrostatic chuck 13, and an edge ring 14. In addition, for example, an electrode plate (not illustrated) made of aluminum may be provided on the lower surface side of the lower electrode 12.

The lower electrode 12 is made of a conductive material, for example, metal such as aluminum, and has a substantially disc-like shape.

In addition, the stage 11 may include a temperature control module configured to control at least one of the electrostatic chuck 13, the edge ring 14, and the wafer W to have a desired temperature. The temperature control module may include a heater, a flow path, or a combination thereof. A temperature control medium, such as a refrigerant or a thermal gas, flows through the flow path.

In one example, a flow path 15a is formed inside the lower electrode 12. The temperature control medium is supplied to the flow path 15a through an inlet pipe 15b from a chiller unit (not illustrated) provided outside the plasma processing chamber 10. The temperature control medium supplied to the flow path 15a returns to the chiller unit through an outlet flow path 15c. The temperature control medium, for example, a coolant such as cooling water is circulated inside the flow path 15a. In this manner, the electrostatic chuck 13, the edge ring 14, and the wafer W may be cooled to a desired temperature.

The electrostatic chuck 13 is installed on the lower electrode 12. In one example, the electrostatic chuck 13 is designed to hold both the wafer W and the edge ring 14 in place using electrostatic force. In the electrostatic chuck 13, an upper surface in a central portion is formed higher than an upper surface of a peripheral edge portion. The central upper surface serves as the wafer mounting surface for placing the wafer W, and in one example, the peripheral edge surface of the electrostatic chuck 13 serves as the edge ring mounting surface for placing the edge ring 14.

In one example, a first electrode 16a, used to hold the wafer W in place, is embedded in the central portion of the electrostatic chuck 13. A second electrode 16b, used to hold the edge ring 14 in place, is embedded in the peripheral edge portion of the electrostatic chuck 13. The electrostatic chuck 13 has a configuration in which the electrodes 16a and 16b are embedded between insulating materials.

A DC voltage from a DC power supply (not illustrated) is applied to the first electrode 16a. The applied DC voltage generates an electrostatic force that holds the wafer W on the central upper surface of the electrostatic chuck 13. Similarly, a DC voltage from the DC power supply (not illustrated) is applied to the second electrode 16b. In one example, the applied DC voltage generates an electrostatic force that holds the edge ring 14 on the peripheral upper surface of the electrostatic chuck 13.

In addition, in the present embodiment, the central portion of the electrostatic chuck 13 where the first electrode 16a is provided, and the peripheral edge portion where the second electrode 16b is provided, are integrally formed, but the central portion and the peripheral portion may be separate components. In addition, both the first electrode 16a and the second electrode 16b may be unipolar or bipolar.

In addition, in the present embodiment, the edge ring 14 is electrostatically held on the electrostatic chuck 13 by applying the DC voltage to the second electrode 16b, but a method for maintaining the edge ring 14 is not limited thereto. For example, the edge ring 14 may be secured using a suction sheet, or clamped in pace. Alternatively, the edge ring 14 may be held in place by its own weight.

The edge ring 14 is an annular member positioned around the wafer W mounted on the upper surface in the central portion of the electrostatic chuck 13. The edge ring 14 is provided to improve uniformity of etching. For this reason, the edge ring 14 is made of a material appropriately selected based on the etching conditions, and may be made of Si or SiC, for example.

The stage 11 configured as described above is secured to a support member 17 having a substantially cylindrical shape provided in a lower portion of the plasma processing chamber 10. The support member 17 is made of an insulating material such as ceramic or quartz, for example.

A shower head 20 is provided on the upper side of the stage 11 to face the stage 11. The shower head 20 includes an electrode plate 21 arranged in contact with the processing space S, and an electrode support body 22 provided on an upper side of the electrode plate 21. The electrode plate 21, together with the lower electrode 12, functions as a pair of upper and lower electrodes. When a source RF power supply 50 is electrically coupled to the lower electrode 12 as described later, the shower head 20 is connected to the ground potential. In addition, the shower head 20 is supported on the ceiling of the plasma processing chamber 10 via an insulating shield member 23.

Multiple gas outlets 21a are formed in the electrode plate 21 to supply process gas from the gas diffusion chamber 22a (described later) to the processing space S. For example, the electrode plate 21 is made of a conductor or semiconductor with low electrical resistivity and minimal Joule heating.

The electrode support body 22 allows the electrode plate 21 to be easily attached and detached. The electrode support body 22 is made of a conductive material, such as aluminum, with a plasma-resistant coating on its surface. This coating may be an anodized layer or a ceramic layer made of materials such as yttrium oxide. The gas diffusion chamber 22a is formed inside the electrode support body 22. A plurality of gas distribution holes 22b communicating with the gas outlet 21a are formed in the gas diffusion chamber 22a. In addition, a gas introduction hole 22c connected to a gas supply pipe 33 (to be described later) is formed in the gas diffusion chamber 22a.

In addition, a gas supply source group 30 for supplying the process gas to the gas diffusion chamber 22a is connected to the electrode support body 22 via a flow control device group 31, a valve group 32, the gas supply pipe 33, and the gas introduction hole 22c.

The gas supply source group 30 includes a plurality of gas supply sources required for etching. The flow control device group 31 includes a plurality of flow controllers, and the valve group 32 includes a plurality of valves. Each of the plurality of flow controllers of the flow control device group 31 is a mass flow controller or a pressure-controlled flow controller. In the etching apparatus 1, the process gas from one or more gas supply sources selected from the gas supply source group 30 is supplied to the gas diffusion chamber 22a through the flow control device group 31, the valve group 32, the gas supply pipe 33, and the gas introduction hole 22c. The process gas supplied to the gas diffusion chamber 22a is dispersed in a shower-like manner and supplied into the processing space S through the gas distribution hole 22b and the gas outlet 21a.

At the lower portion of the plasma processing chamber 10, a baffle plate 40 is provided between an inner wall of the plasma processing chamber 10 and the support member 17. For example, the baffle plate 40 is formed by coating an aluminum material with ceramic such as yttrium oxide. A plurality of through-holes are formed in the baffle plate 40. The processing space S is connected with the exhaust port 41 via the baffle plate 40. An exhaust device 42 such as a vacuum pump is connected to the exhaust port 41, and the inside of the processing space S is configured to be depressurized by the exhaust device 42.

In addition, an inlet/outlet 43 of the wafer W is formed on a side wall of the plasma processing chamber 10, and the inlet/outlet 43 may be opened or closed by a gate valve 44.

As illustrated in FIGS. 1 and 2, the etching apparatus 1 further includes the source RF power supply 50, the bias RF power supply 51, and a matching circuit 52. The source RF power supply 50 and the bias RF power supply 51 are coupled to the lower electrode 12 through the matching circuit 52.

The source RF power supply 50 generates source RF power HF for plasma generation, and supplies the source RF power HF to the lower electrode 12. The source RF power HF has a frequency within a range of 27 MHz to 100 MHZ, and the frequency is 40 MHz in one example. The source RF power supply 50 is coupled to the lower electrode 12 through a first matching circuit 53 of the matching circuit 52. The first matching circuit 53 is a circuit for matching an output impedance of the source RF power supply 50 and an input impedance of the lower electrode 12 side on a load side. In addition, the source RF power supply 50 does not have to be electrically coupled to the lower electrode 12, and may be coupled to a shower head 20 which is the upper electrode, through the first matching circuit 53. In addition, instead of the source RF power supply 50, a pulse power supply configured to apply a pulse voltage other than the source RF power HF to the lower electrode 12 may be used. This pulse power supply is similar to a pulse power supply used instead of the bias RF power supply 51 (to be described later).

The bias RF power supply 51 generates the bias RF power LF for attracting the ions to the wafer W, and supplies the bias RF power LF to the lower electrode 12. The bias RF power LF has a frequency within a range of 400 kHz to 13.56 MHz, and the frequency is 400 kHz in one example. The bias RF power supply 51 is coupled to the lower electrode 12 through a second matching circuit 54 of the matching circuit 52. The second matching circuit 54 is a circuit for matching the output impedance of the bias RF power supply 51 and the input impedance of the lower electrode 12 side on the load side. In addition, instead of the bias RF power supply 51, a pulse power supply configured to apply a pulse voltage other than the bias RF power LF to the lower electrode 12 may be used. Here, the pulse voltage is a periodically varying voltage with a pulse waveform. The pulse power supply may be a DC power supply. The pulse power supply may be configured so that the power supply itself applies the pulse voltage, or may be configured to have a device for pulsing the voltage on a downstream side. In one example, the pulse voltage is applied to the lower electrode 12 to generate a negative potential on the wafer W. The pulse voltage may be a square wave, a triangular wave, an impulse, or may have another waveform. The frequency of the pulse voltage (pulse frequency) may be a frequency within a range of 100 KHz to 2 MHZ. In addition, the bias RF power LF or pulse voltage may be supplied or applied to the bias electrode provided within the electrostatic chuck 13.

The etching apparatus 1 further includes a direct current (DC) power supply 60, a switching unit 61, a first RF filter 62, and a second RF filter 63. The DC power supply 60 is electrically connected to the edge ring 14 via the switching unit 61, the second RF filter 63, and the first RF filter 62. In addition, in the present embodiment, the DC power supply 60 is connected to the ground potential.

The DC power supply 60 is a power supply that generates a negative DC voltage applied to the edge ring 14. In addition, the DC power supply 60 is a variable DC power supply, and the level of the DC voltage may be adjusted.

The switching unit 61 is configured to stop the application of the DC voltage from the DC power supply 60 to the edge ring 14. In addition, a circuit configuration of the switching unit 61 may be appropriately designed by those skilled in the art.

The first RF filter 62 and the second RF filter 63 are filters that respectively attenuate the RF power. For example, the first RF filter 62 attenuates the source RF power HF of 40 MHz from the source RF power supply 50. For example, the second RF filter 63 attenuates the bias RF power LF of 400 kHz from the bias RF power supply 51.

In one example, the second RF filter 63 is configured to have the variable impedance. That is, the second RF filter 63 includes at least one variable passive element, allowing for adjustable impedance. In the following description, the impedance of the second RF filter 63 and the impedance of the variable passive element are synonymous. For example, the second variable passive element may be any one of a coil (inductor) or a condenser (capacitor). In addition, without being limited to the coil or the condenser, any variable impedance element such as diodes may achieve the same function. The number and positions of the variable passive elements may also be appropriately designed by those skilled in the art. In addition, the element itself does not need to be variable. For example, a plurality of elements having fixed impedance values may be provided, and the impedance may be varied by using a switching circuit to change a combination of the elements having the fixed values. In addition, the circuit configurations of both the second RF filter 63 and the first RF filter 62 may be appropriately designed by those skilled in the art.

The etching apparatus 1 may further include a measuring device (not illustrated) for measuring a self-bias voltage of the edge ring 14 or a self-bias voltage of the lower electrode 12 or the wafer W. In addition, those skilled in the art may appropriately design a configuration of the measuring device.

The etching apparatus 1 described above is provided with the controller 100. For example, the controller 100 is a computer equipped with a CPU, a memory, and the like, and includes a program storage unit (not illustrated). The program storage stores a program that controls the etching process in the etching apparatus 1. In addition, the program may be recorded on a computer-readable storage medium, and may be installed in the controller 100 from the storage medium. In addition, the storage medium may be temporary or non-temporary.

### <Etching Method>

Next, etching performed by using the etching apparatus 1 configured as described above will be described.

First, the wafer W is introduced into the plasma processing chamber 10, and the wafer W is mounted on the electrostatic chuck 13. Then, a DC voltage is applied to the first electrode (16a) of the electrostatic chuck (13), causing the wafer (W) to be electrostatically attracted and held in place by Coulomb force. In addition, after the wafer W is introduced, the plasma processing chamber 10 is internally depressurized to a desired vacuum level by the exhaust device 42.

Next, the process gas is supplied to the processing space S from the gas supply source group 30 through the shower head 20. In addition, the source RF power HF for generating the plasma is supplied to the lower electrode 12 by the source RF power supply 50, and the process gas is excited to generate the plasma. In this case, bias RF power (LF) for ion acceleration may be supplied by the bias RF power supply (51). Etching is performed on the wafer W by an action of the generated plasma.

To conclude the etching process, first, the supply of the source RF power HF from the source RF power supply 50 and the supply of the process gas by the gas supply source group 30 are stopped. In addition, when the bias RF power LF is supplied during the etching, the supply of the bias RF power LF is also stopped. Next, the supply of a heat transfer gas to a back surface of the wafer W is stopped, and the electrostatic chuck (13) releases its hold on the wafer (W).

Thereafter, the wafer W is taken out from the plasma processing chamber 10, and a series of etching operations on the wafer W are completed.

In addition, in some cases of the etching, the plasma may be generated by using only the bias RF power LF from the bias RF power supply 51, without using the source RF power HF from the source RF power supply 50.

### <Tilt Angle Control Method>

Next, a method for controlling a tilt angle in the etching described above will be described. The tilt angle refers to the inclination of a recessed feature formed by etching in the edge region of the wafer (W) relative to its thickness direction. The tilt angle is approximately equal to the incident angle of ions in the vertical direction at the wafer's edge region. In the following description, the direction toward the wafer's center along its thickness will be referred to as the ‘inner side,’ while the direction outward along its thickness will be referred to as the ‘outer side.’

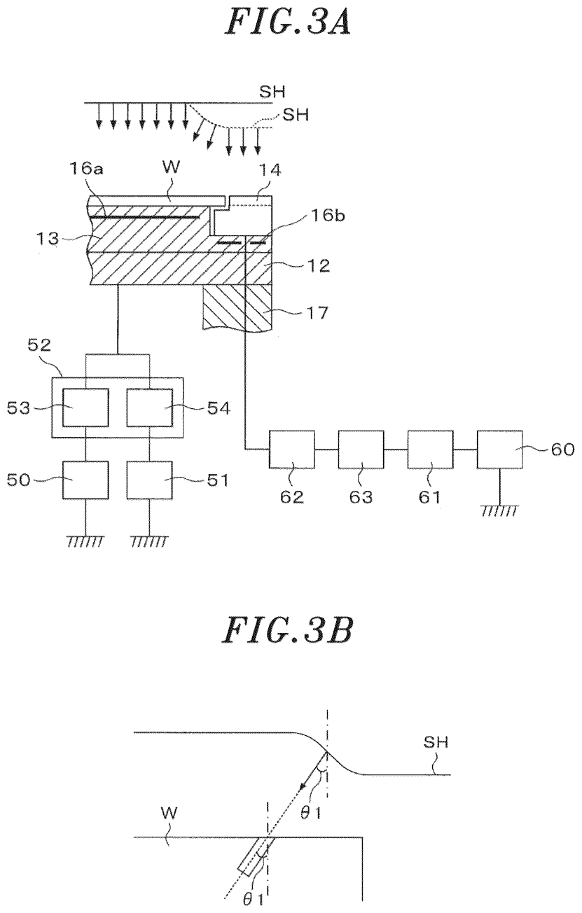

FIGS. 3A and 3B illustrate changes in sheath shape and ion incident angle caused by edge ring wear. The edge ring 14 indicated by a solid line in FIG. 3A represents the edge ring 14 in a state where there is no consumption. The edge ring 14 indicated by a dotted line represents the edge ring 14 whose thickness is decreased due to the consumption. In addition, a sheath SH indicated by a solid line in FIG. 3A represents the shape of the sheath SH when the edge ring 14 is not in a consumed state. The sheath SH indicated by a dotted line represents the shape of the sheath SH when the edge ring 14 is in a consumed state. In addition, an arrow in FIG. 3A represents the incident direction of the ions when the edge ring 14 is in the consumed state.

As illustrated in FIG. 3a, in one example, when the edge ring 14 is not in the consumed state, the shape of the sheath SH is maintained flat on the upper side of the wafer W and the edge ring 14. As a result, ions strike the wafer (W) in a vertical direction, nearly perpendicular to its surface. Therefore, the tilt angle becomes zero degrees.

Meanwhile, when the edge ring 14 is consumed and the thickness is reduced, the thickness of the sheath SH in the edge region of the wafer W and on the upper side of the edge ring 14 is reduced, and the shape of the sheath SH is changed to a convex downward shape. As a result, the ion incidence angle at the wafer's edge deviates from the vertical direction. In the following description, when the incident direction of the ions is tilted toward the radially inner center side with respect to the vertical direction, a phenomenon in which the recessed feature formed by the etching is tilted toward the inner side will be referred to as inner tilt. In FIG. 3b, the incident direction of the ions is tilted toward the inner side at an angle θ1, and the recessed feature is also tilted toward an inner side at the angle θ1. A cause of the inner tilt is not limited to the consumption of the edge ring 14 described above. For example, if the bias voltage of the edge ring 14 is lower than that of the wafer W, inner tilt can occur from the outset. For example, in the initial state of the edge ring 14, in some cases, the tilt angle may be corrected by intentionally adjusting the tilt angle to the inner tilt, and by adjusting at least one of the DC voltage from the DC power supply 60 described later and the impedance of the second RF filter 63.

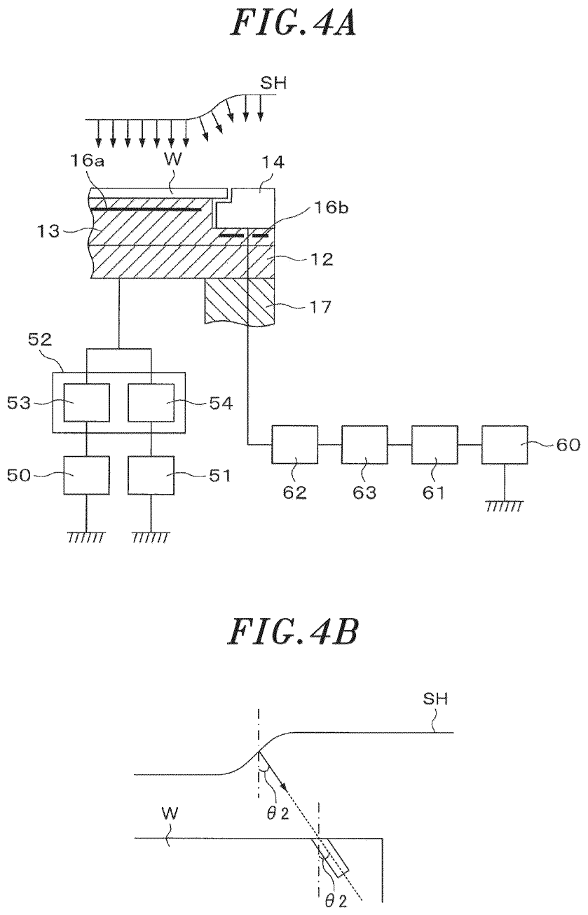

In addition, as illustrated in FIGS. 4A and 4B, in some cases, with respect to the central region of the wafer W, the thickness of the sheath SH may increase in the edge region of the wafer W and on the upper side of the edge ring 14, and the shape of the sheath SH may become a convex upward shape. For example, when the bias voltage generated in the edge ring 14 is high, the shape of the sheath SH may become a convex upward shape. In FIG. 4A, an arrow indicates the incident direction of the ions. In the following description, when the incident direction of the ions is tilted radially outward with respect to the vertical direction, a phenomenon in which the recessed feature formed by the etching is tilted toward the outer side will be referred to as outer tilt. In FIG. 4B, the incident direction of the ions is tilted toward the outer side by an angle θ2, and the recessed feature is also tilted toward the outer side by the angle θ2.

In the etching apparatus 1 of the present embodiment, the tilt angle is controlled. Specifically, the tilt angle is controlled by controlling the incident angle of the ions by adjusting at least one of the DC voltage from the DC power supply 60 and the impedance of the second RF filter 63.

### [Adjustment of DC Voltage]

First, adjustment of the DC voltage from the DC power supply 60 will be described. In the DC power supply 60, the DC voltage applied to the edge ring 14 is set to a negative value in which a sum of an absolute value of the self-bias voltage Vdc and a set value ΔV is an absolute value, that is, −(|Vdc|+ΔV). The self-bias voltage Vdc is a self-bias voltage of the wafer W, and is a self-bias voltage of the lower electrode 12 when at least some RF power is supplied and the DC voltage from the DC power supply 60 is not applied to the lower electrode 12. The set value ΔV is provided by the controller 100.

The controller 100 determines the set value ΔV using a predefined function or lookup table based on the edge ring's consumption, the reduction in its thickness from its initial value, and the estimated consumption derived from etching process conditions, such as processing time. That is, the controller 100 determines the set value ΔV by inputting the edge ring's consumption and self-bias voltage into the function or by referencing the lookup table using these values.

In determining the set value ΔV, the controller 100 may use a difference between an initial thickness of the edge ring 14 and the thickness of the edge ring 14 actually measured by using a measuring device such as a laser measuring device or a camera, as the consumption amount of the edge ring 14. In addition, the consumption amount of the edge ring 14 may be estimated from a change in the mass of the edge ring 14 which is measured by using a measuring device such as a mass meter. Alternatively, the controller 100 may estimate the edge ring's consumption from a specific parameter using a predefined function or lookup table to determine the set value ΔV. The specific parameter may be any one of the self-bias voltage Vdc, the voltage Vpp of the source RF power HF or the bias RF power LF, a load impedance, an electrical characteristic of the edge ring 14 or a periphery of the edge ring 14, and the like. The electrical characteristic of the edge ring 14 or the periphery of the edge ring 14 may be any one of a voltage, a current value, a resistance value including the edge ring 14, and the like at any location of the edge ring 14 or the periphery of the edge ring 14. Another function or table is determined in advance to determine a relationship between a specific parameter and the consumption amount of the edge ring 14. To estimate the edge ring's 14 consumption, the etching apparatus 1 operates under predefined measurement conditions before actual etching or during maintenance. These conditions include the source RF power HF, bias RF power LF, processing space S pressure, and process gas flow rate. The specific parameter is then obtained and entered into the function or used to reference the lookup table, determining the edge ring's (14) consumption.

In the etching apparatus 1, during the etching, that is, during a period in which at least some RF power from the source RF power HF and the bias RF power LF are supplied, a DC voltage is applied to the edge ring 14 from the DC power supply 60. In this manner, the shape of the sheath in the edge ring 14 and on the upper side of the edge region of the wafer W is controlled. The tilting in the incident direction of the ions on the edge region of the wafer W is reduced, and the tilt angle is controlled. As a result, the recessed feature which is substantially parallel in the thickness direction of the wafer W is formed over the entire region of the wafer W.

More specifically, during etching, the self-bias voltage Vdc is measured by a measuring device (not illustrated). In addition, a DC voltage is applied to the edge ring 14 from the DC power supply 60. The applied DC voltage to the edge ring 14 is set to −(|Vdc|+ΔV) as described above. Here, |Vdc| represents the absolute value of the self-bias voltage Vdc measured just prior, while ΔV is a set value determined by the controller 100. In this way, the DC voltage applied to the edge ring 14 is determined from the self-bias voltage Vdc measured during the etching. In this way, even when there is a change in the self-bias voltage Vdc, the DC voltage generated by the DC power supply 60 is corrected, and the tilt angle is appropriately corrected.

### [Adjustment of Impedance]

Next, the adjustment of the impedance in the second RF filter 63 will be described.

The controller 100 determines the impedance of the second RF filter 63 based on the edge ring's 14 consumption, similar to how it sets the DC voltage from the DC power supply 60, as described above. By adjusting the impedance of the second RF filter 63, the controller 100 modifies the voltage generated in the edge ring 14.

In the etching apparatus 1, during etching, the second RF filter 63 is controlled to the impedance set in the controller 100. This regulates the sheath shape above the edge ring (14) and the upper portion of the wafer's (W) edge region. Accordingly, the tilting in the incident direction of the ions on the edge region of the wafer W is reduced, and the tilt angle is controlled.

### [Adjustment of DC Voltage and Impedance]

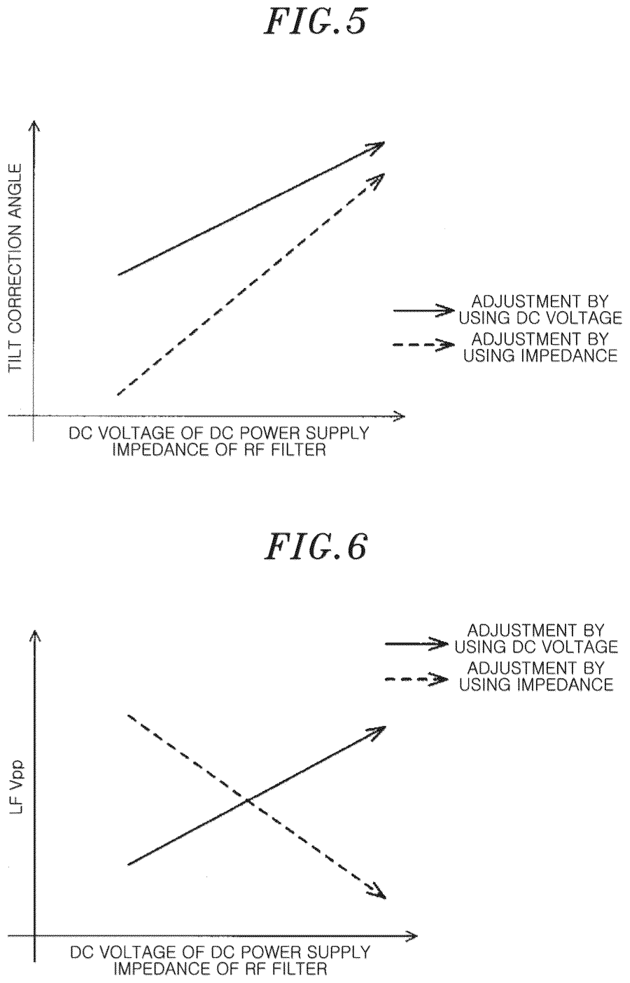

FIG. 5 is a diagram for describing a relationship between the DC voltage from the DC power supply 60 or the impedance of the second RF filter 63 and the correction angle of the tilt (hereinafter, referred to as a “tilt correction angle”). The vertical axis in FIG. 5 represents the tilt correction angle, while the horizontal axis represents the DC voltage or the impedance. As illustrated in FIG. 5, when the absolute value of the DC voltage from the DC power supply 60 is increased, the tilt correction angle increases. In addition, the tilt correction angle also increases by increasing the impedance of the second RF filter 63. In addition, in an example illustrated in FIG. 5, the tilt correction angle is increased by increasing the impedance, but depending on a configuration of the second RF filter 63, the tilt correction angle may be decreased by increasing the impedance. The relationship between impedance and the tilt correction angle is not fixed, as it depends on the design of the second RF filter 63. Additionally, the resolution of tilt angle correction—whether by adjusting the DC voltage or impedance—depends on the performance of the DC power supply (60) and the second RF filter 63, respectively. The resolution of tilt angle correction refers to the amount of correction achieved per single adjustment of the DC voltage or impedance.

The tilt angle is controlled by adjusting the DC voltage from the DC power supply 60 and/or the impedance of the second RF filter 63, depending on the wear/consumption of the edge ring 14. For example, the tilt angle may be controlled by adjusting only the DC voltage from the DC power supply 60, or the tilt angle may be controlled by adjusting only the impedance of the second RF filter 63. In addition, the tilt angle may be controlled by adjusting both the DC voltage from the DC power supply 60 and the impedance of the second RF filter 63.

Specifically, as shown in FIGS. 3A and 3B, when the edge ring 14 wears down, the ion incidence angle tilts inward relative to the vertical direction, resulting in inner tilt. Therefore, as illustrated in FIG. 5, when at least one of the absolute value of the DC voltage from the DC power supply 60 and the impedance of the second RF filter 63 is increased, the tilt correction angle increases. In this way, an inward-tilted angle can be shifted outward, ultimately correcting the tilt angle to zero degrees.

In addition, in the present embodiment, although at least one of the DC voltage from the DC power supply 60 and the impedance of the second RF filter 63 is adjusted in accordance of the consumption amount of the edge ring 14, the timing of DC voltage or impedance adjustment is not restricted to this method. For instance, the DC voltage or impedance can be adjusted based on the wafer's processing time. Alternatively, for example, the timing for adjusting the DC voltage or the impedance may be determined by combining the processing time of the wafer W and the predetermined parameters, for example, such as radio frequency power.

### <Method for Controlling Voltage Vpp of Bias RF Power LF>

Next, in the above-described etching, a method for controlling the voltage Vpp of the bias RF power LF (hereinafter, referred to as “LF Vpp” will be described.

FIG. 6 is a diagram for describing a relationship between the DC voltage from the DC power supply 60 or the impedance of the second RF filter 63 and LF Vpp. The vertical axis in FIG. 6 represents the LF Vpp, while the horizontal axis represents the DC voltage or the impedance. Through careful analysis, the inventor discovered the following. As illustrated in FIG. 6, when the absolute value of the DC voltage from the DC power supply 60 is increased, the LF Vpp increases, but when the impedance of the second RF filter 63 is increased, the LF Vpp decreases. That is, when the impedance of the second RF filter 63 is adjusted, the tilt angle may be controlled, and at the same time, the LF Vpp may be controlled. Based on this finding, the LF Vpp is controlled.

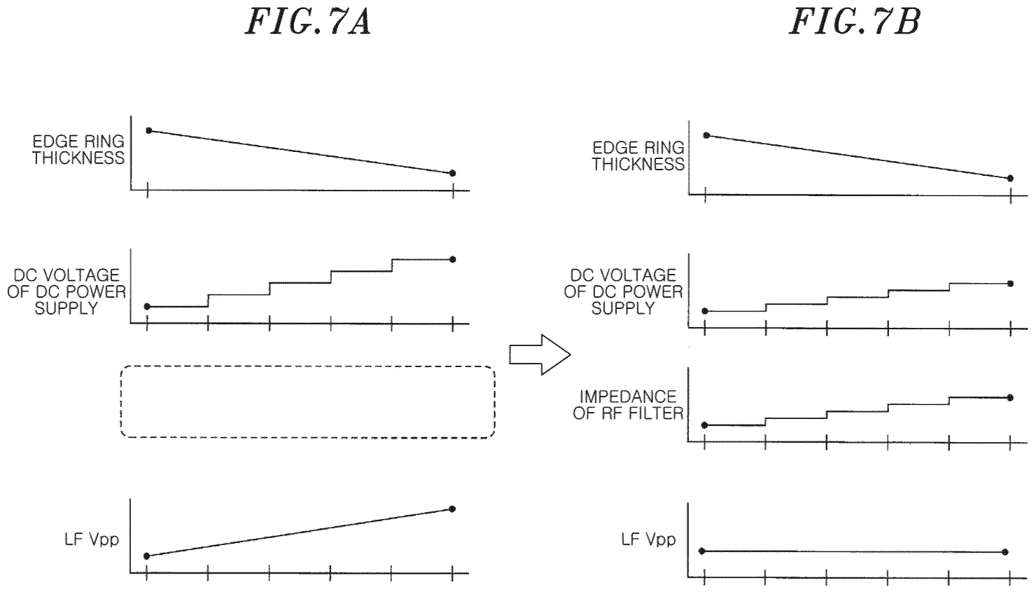

During the etching in the etching apparatus 1, for example, when the thickness of the edge ring 14 decreases in accordance with the consumption of the edge ring 14 as illustrated in FIG. 7A, the absolute value of the DC voltage from the DC power supply 60 is increased. The DC voltage is determined based on controllability of the tilt angle. When the absolute value of the DC voltage is increased in this way, the LF Vpp increases.

Therefore, as illustrated in FIG. 7B, the DC voltage is increased, and the impedance of the second RF filter 63 is also increased. When the impedance is increased in this way, the LF Vpp decreases due to the relationship illustrated in FIG. 6. That is, an increase in the LF Vpp due to the adjustment of the DC voltage is offset by a decrease in the LF Vpp due to the adjustment of the impedance. In this way, the LF Vpp may be controlled to fall within a stable or permissible range. In addition, the permissible range is set according to the specifications required for the etching process.

According to the present embodiment, the tilt angle may be controlled by adjusting the DC voltage from the DC power supply 60 and the impedance of the second RF filter 63, and in addition, the LF Vpp may be appropriately adjusted by adjusting the impedance. That is, the LF Vpp control during the tilt angle control may be realized. Furthermore, this control is achieved without modifying the apparatus configuration.

In addition, as described above, in conventional methods, the LF Vpp is adjusted by adjusting the RF power. Accordingly, the adjustment of the RF power may have an influence on heat input to the wafer, or may have an influence on process performance. In contrast, according to the present embodiment, since the LF Vpp may be adjusted by causing the RF power to be constant, the influence on the heat input to the wafer or the process performance in the related art may be suppressed.

In addition, in the present embodiment, as illustrated in FIG. 6, when the impedance of the second RF filter 63 is increased, the LF Vpp is decreased. However, depending on the circuit design of the second RF filter 63 or a measurement location of the LF Vpp, when the impedance is decreased, the LF Vpp may be decreased in some cases. Therefore, in order to decrease the LF Vpp, it is not always necessary to increase the impedance of the second RF filter 63, and the impedance may be adjusted depending on the circuit design of the second RF filter 63 or the measurement location of LF Vpp.

### <Method for Adjusting DC Voltage and Impedance>

As described above, in the present embodiment, the tilt angle and the LF Vpp are controlled by adjusting the DC voltage from the DC power supply 60 and the impedance of the second RF filter 63. In this case, the adjustment of the DC voltage and the adjustment of the impedance may be optionally combined. Hereinafter, an example will be described.

FIG. 8 illustrates an example method for adjusting the DC voltage from the DC power supply (60) and the impedance of the second RF filter 63. In FIG. 8, absolute values V1, V2, V3, and V4 of the DC voltages increase in this order, and impedances Z1, Z2, Z3, and Z4 decrease in this order. In addition, “Edge ring New” indicates a state where the edge ring 14 is new before being consumed, and “Edge ring Life Limit” indicates a state where the edge ring 14 reaches an end of a lifespan and needs to be replaced after being consumed.

As shown in FIG. 8, as the edge ring 14 wears down, the absolute value of the DC voltage is adjusted from V1 to V3, while the impedance is changed from Z3 to Z1. In the present embodiment, the adjustment of the DC voltage and the adjustment of the impedance are simultaneously performed.

As the edge ring (14) wears down, the ion incidence angle shifts toward an inner tilt. As shown in FIG. 5, increasing the absolute value of the DC voltage increases the tilt correction angle. In this way, the inward tilt angle can be shifted outward, effectively correcting the tilt angle to zero degrees. In addition, in this case, since the impedance is reduced, the tilt correction angle decreases. However, after the decrease in the tilt correction angle is considered, the absolute value of the DC voltage is changed so that the tilt angle becomes zero degrees.

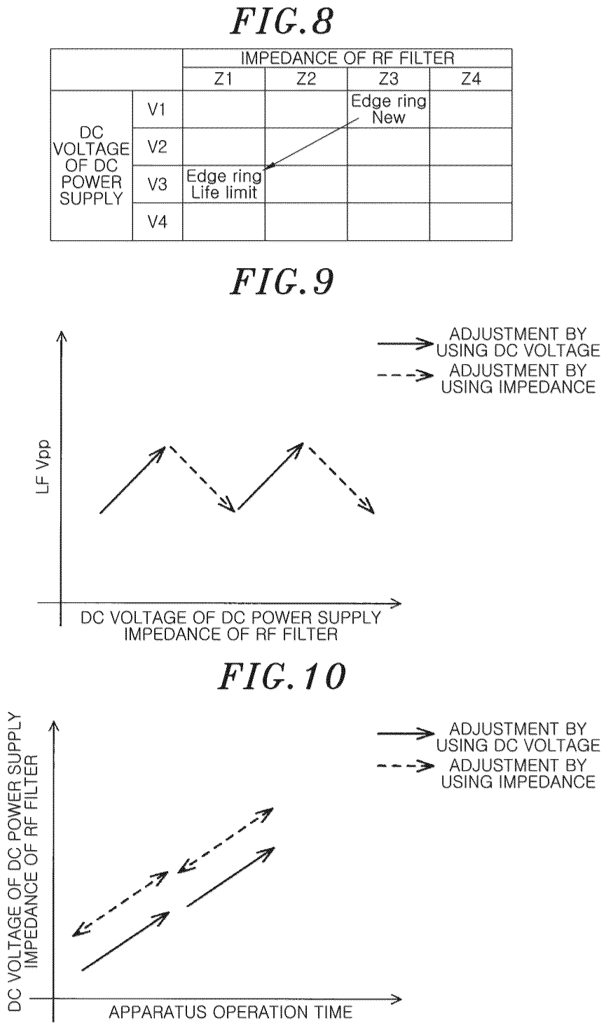

As shown in FIG. 9, increasing the DC voltage raises LF Vpp. However, increasing the impedance lowers LF Vpp, allowing it to be controlled within a stable or permissible range. In addition, the vertical axis in FIG. 9 represents the LF Vpp, and the horizontal axis represents the DC voltage or the impedance.

As explained earlier, the DC voltage and impedance values are set to maintain a tilt angle of zero degrees while keeping LF Vpp within a stable or permissible range. The tilt angle and the LF Vpp may be appropriately controlled.

In addition, in the present embodiment, the DC voltage and the impedance are simultaneously changed and adjusted. However, both of these may be individually adjusted. A timing for adjusting the DC voltage and a timing for adjusting the impedance are set in any desired way. For example, the impedance may be adjusted after the DC voltage is adjusted, or the impedance may be adjusted after the DC voltage is adjusted. In any case, both the tilt angle and the LF Vpp are controlled.

Additionally, in this embodiment, while both DC voltage and impedance are adjusted, it is also possible to control the tilt angle and LF Vpp by disabling the DC voltage output from the power supply (60) and adjusting only the impedance.

Furthermore, in this embodiment, the impedance is adjusted in a single direction from Z3 to Z1, but it may also be increased or decreased, as shown in FIG. 10. In addition, the vertical axis in FIG. 10 represents the DC voltage or the impedance, and the horizontal axis represents an apparatus operation time (process time). In addition, in FIG. 10, a first arrow represents a behavior of the DC voltage and the impedance when the first wafer W is etched, and a second arrow represents a behavior of the DC voltage and the impedance when the second wafer W is etched.

Conventionally, when controlling the tilt angle, the impedance is adjusted in a single direction to increase the tilt correction angle. In contrast, in this embodiment, when LF Vpp is controlled within a stable or permissible range, the impedance can be increased or decreased, as indicated by the bidirectional arrows in FIG. 10. In other words, the impedance may be adjusted regardless of the consumption amount of the edge ring 14, and may be optionally adjusted within a range that does not affect the tilt angle control. LF Vpp increases with changes in DC voltage but can also fluctuate due to other factors. Thus, by adjusting the impedance in response to LF Vpp fluctuations, LF Vpp can be consistently maintained within a stable or permissible range.

Additionally, in this embodiment, the initial impedance is set to Z3, but this starting value can be freely adjusted. As described above, in the present embodiment, the impedance may be increased or decreased, and the starting point may be freely selected.

In this embodiment, the DC voltage and impedance are adjusted between the etching of one wafer (W) and the next. However, the timing of these adjustments is not restricted to this interval. For example, when the etching time for one wafer W is long and the edge ring 14 is consumed during the etching, the DC voltage and the impedance may be adjusted during the etching.

### Another Embodiment

As previously described, the bias RF power (LF) supplied from the bias RF power supply (51) typically operates between 400 kHz and 13.56 MHz, but a frequency of 5 MHz or lower is preferred. For high-aspect-ratio etching on the wafer (W), high ion energy is necessary to achieve vertical pattern profiles post-etching. Therefore, as a result of careful analysis, the present inventors found the followings. Setting the bias RF power (LF) frequency to 5 MHz or lower enhances ion response to changes in the RF electric field, improving ion energy controllability.

However, when the bias RF power (LF) frequency is reduced to 5 MHz or lower, the effectiveness of varying the impedance of the second RF filter (63) may decline. That is, controllability of the tilt angle by adjusting the impedance of the second RF filter 63 may be degraded. For instance, as shown in FIG. 2, if the electrical connection between the edge ring 14 and the second RF filter 63 is non-contact or capacitively coupled, adjusting the impedance of the second RF filter 63 may not effectively control the tilt angle. To address this, in this embodiment, the edge ring 14 and the second RF filter 63 are directly connected electrically.

The edge ring 14 and the second RF filter 63 are electrically directly connected through the connection portion. The edge ring 14 and the connection portion are in contact, and a DC current from the DC power supply 60 flows through the connection portion. Hereinafter, an example of a structure of the connection portion (hereinafter, may be referred to as a “contact structure”) will be described.

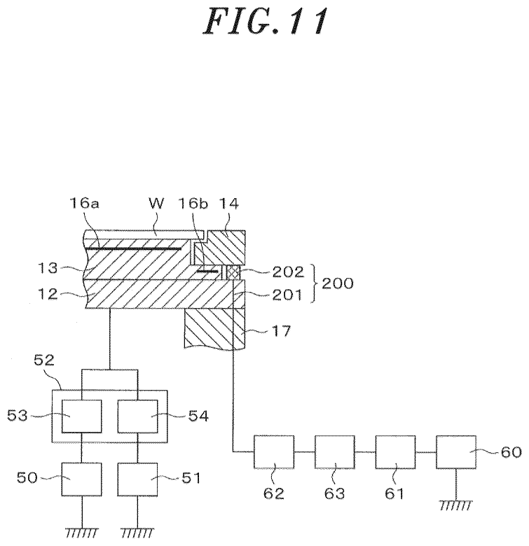

As illustrated in FIG. 11, a connection portion 200 as a conductor includes a conductive structure 201 and a conductive elastic member 202. The conductive structure 201 connects the edge ring 14 to the second RF filter 63 via the conductive elastic member 202. Specifically, one end of the conductive structure 201 is connected to the second RF filter 63. The other end is exposed on an upper surface of the lower electrode 12, and is in contact with the conductive elastic member 202.

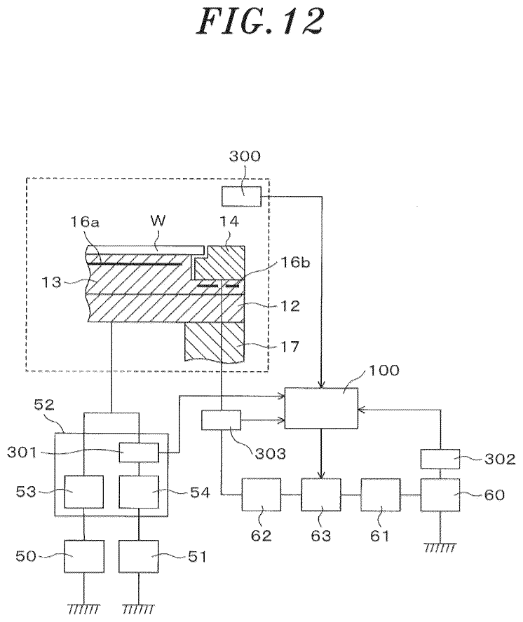

For example, the conductive elastic member 202 is placed in the space between the lower electrode 12 and the edge ring 14, adjacent to the electrostatic chuck 13. The conductive elastic member 202 makes contact with both the conductive structure 201 and a lower surface of the edge ring 14. In addition, the conductive elastic member 202 is made of a conductor such as a metal, for example. A configuration of the conductive elastic member 202 is not particularly limited, but, for example, a configuration illustrated in FIGS. 11A to 11F of Japanese Laid-open Patent Publication No. 2022-7865 is disclosed as an example. In addition, an arrangement of the conductive elastic member 202 in a plan view is also not particularly limited, but, for example, an arrangement illustrated in FIGS. 12A to 12C of Japanese Laid-open Patent Publication No. 2022-7865 is disclosed as an example.

In this case, as illustrated in FIG. 11, the edge ring 14 and the second RF filter 63 may be directly connected electrically via the connection portion 200. This allows the bias RF power LF frequency to be set at 5 MHz or lower, improving ion energy controllability. Additionally, as mentioned earlier, the tilt angle can be precisely controlled by adjusting the impedance of the second RF filter (63), expanding its adjustment range.

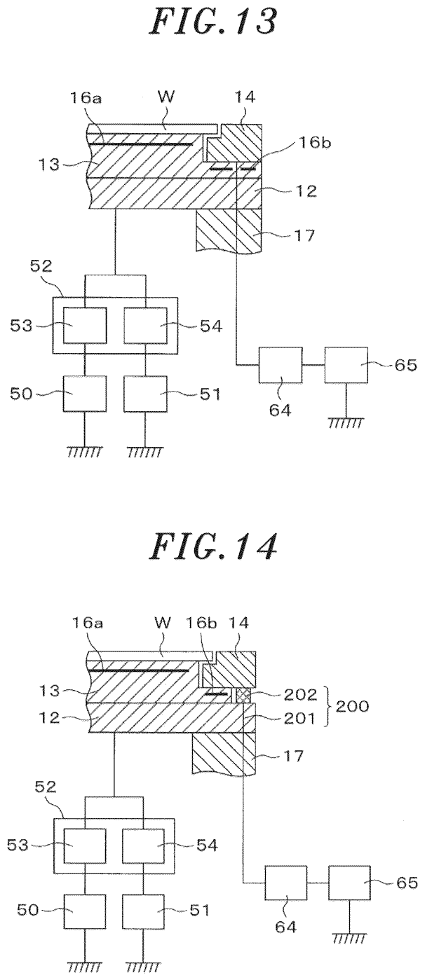

In addition, a structure for contact with the edge ring 14 is not limited to the example illustrated in FIG. 11. For example, the configuration illustrated in FIGS. 13A to 13G of Japanese Laid-open Patent Publication No. 2022-7865 may be adopted. Moreover, the relationship between the connection portion 200, the first RF filter 62, and the second RF filter 63 is not strictly defined. However, configurations shown in FIGS. 14A to 14C of Japanese Laid-Open Patent Publication No. 2022-7865 serve as examples.

### Another Embodiment

In the above-described embodiment, the DC power supply 60 is connected to the edge ring 14 via the switching unit 61, the first RF filter 62, and the second RF filter 63, but the power supply system for applying the DC voltage to the edge ring 14 is not limited thereto. For example, the DC power supply 60 may be electrically connected to the edge ring 14 via the switching unit 61, the second RF filter 63, the first RF filter 62, and the lower electrode 12. In this case, the lower electrode 12 and the edge ring 14 are directly electrically coupled, and the self-bias voltage of the edge ring 14 becomes equal to the self-bias voltage of the lower electrode 12.

When the lower electrode (12) and the edge ring (14) are directly electrically coupled, the sheath thickness on the edge ring (14) may become unadjustable due to capacitance effects from the rigid structure beneath it. As a result, an outer tilt state may arise even if no DC voltage is applied. To address this, the present disclosure proposes controlling the tilt angle by adjusting the DC voltage from the DC power supply (60) and the impedance of the second RF filter (63). Therefore, the tilt angle may be adjusted to zero degrees by changing the tilt angle toward the inner side.

### Another Embodiment

In the above-described embodiment, the source RF power HF and the bias RF power supply 51 are used as the RF power supplies, but the number of the RF power supplies is not limited thereto. For example, a single RF power supply may supply single-frequency RF power, or three RF power supplies may supply three-frequency RF power.

### Another Embodiment

In the previous embodiment, the impedance of the second RF filter 63 was adjustable. However, the impedance of the first RF filter 62 could also be made adjustable, or both RF filters 62 and 63 could have variable impedances. In this case, the first RF filter 62 may attenuate the bias RF power LF, and the LF Vpp may be controlled by adjusting the impedance of the first RF filter 62. Alternatively, when it is necessary to control the voltage Vpp of the source RF power HF (hereinafter, referred to as “HF Vpp”) together with the LF Vpp, the HF Vpp may be controlled by adjusting the impedance of the first RF filter 62, and the LF Vpp may be controlled by adjusting the impedance of the second RF filter 63.

In addition, in the above-described embodiment, two RF filters 62 and 63 are provided for the DC power supply 60, but the number of the RF filters is not limited thereto. For example, two RF filters 62 and 63 may be integrated to provide one RF filter. Alternatively, three or more RF filters may be provided.

In addition, in the above-described embodiment, the second RF filter 63 (first RF filter 62) includes at least one variable passive element so that the impedance is variable, but a configuration for causing the impedance to be variable is not limited thereto. For example, variable or fixed impedance RF filters 62 and 63 may be connected to a device capable of varying the impedance of the RF filters 62 and 63. That is, the RF filters 62 and 63 having variable impedance may be configured by the RF filter and a device connected to the RF filter and capable of varying the impedance of the RF filter. In addition, the RF filters 62 and 63 include at least one variable passive element so that the impedance is variable. However, the variable passive element may be provided outside the RF filters 62 and 63 by using the impedance which is not variable.

### Another Embodiment

In the above-described embodiment, the etching apparatus 1 may include a sensor for controlling the LF Vpp. FIG. 12 is a diagram for describing the sensor for controlling the LF Vpp in the etching apparatus 1.

As illustrated in FIG. 12, the etching apparatus 1 includes an in-chamber sensor 300, a matching circuit sensor 301, a DC power sensor 302, and a filter path sensor 303. For each of the sensors 300, 301, 302, and 303, a sensor is used depending on a measurement target. For example, a voltage sensor, a contact sensor, a non-contact sensor, an optical sensor, and the like are used.

As an example, the in-chamber sensor 300 may measure the LF Vpp inside the plasma processing chamber 10. In addition, as an example, the in-chamber sensor 300 may measure/collect information on the LF Vpp inside the plasma processing chamber 10, such as a voltage, a current (magnetic field), power, system load parameters (including the impedance, forward power, and reflected power). From the information on the LF Vpp, the LF Vpp may be calculated and estimated. The in-chamber sensor 300 may be provided at any location inside the plasma processing chamber 10, and for example, may be provided inside a path connecting the matching circuit 52 and the plasma processing chamber 10, inside a pipe for supplying the RF power, inside the electrostatic chuck 13, or the like. In addition, the in-chamber sensor 300 may be provided outside the plasma processing chamber 10. Information measured/collected by the in-chamber sensor 300 is transmitted to the controller 100.

As an example, the matching circuit sensor 301 may measure the LF Vpp inside the matching circuit 52. In addition, as an example, the matching circuit sensor 301 may measure/collect information on the LF Vpp inside the matching circuit 52, for example, a voltage and system load parameters (including the impedance, forward power, and reflected power). From the information on the LF Vpp, the LF Vpp may be calculated and estimated. The matching circuit sensor 301 may be provided at any position inside the matching circuit 52, and for example, may be provided inside the first matching circuit 53, inside the second matching circuit 54, at an outlet of the matching circuits 53 and 54. In addition, the matching circuit sensor 301 may be provided outside the matching circuit 52. Information measured/collected by the matching circuit sensor 301 is output to the controller 100.

As an example, the DC power sensor 302 may measure information on the LF Vpp in the DC power supply 60, for example, a DC voltage (output voltage), a DC current (output current), a radio frequency noise voltage, a radio frequency noise current, and the like from the DC power supply 60. From the information on the LF Vpp, the LF Vpp may be calculated and estimated. The DC power sensor 302 is provided inside or outside the DC power supply 60. Information measured/collected by the DC power sensor 302 is output to the controller 100.

As an example, the filter path sensor 303 may measure information on the LF Vpp inside the filter path, for example, the voltage, the current (magnetic field), and the like. From the information on the LF Vpp, the LF Vpp may be calculated and estimated. The filter path sensor 303 may be provided at any position inside the filter path, for example, may be provided inside the path between the RF filters 62 and 63 and the edge ring 14. In addition, the filter path sensor 303 may be provided inside the RF filters 62 and 63. Information measured/collected by the filter path sensor 303 is output to the controller 100.

The controller 100 collects and processes information output from the in-chamber sensor 300, the matching circuit sensor 301, the DC power sensor 302, and the filter path sensor 303, and outputs an instruction for the second RF filter 63. Specifically, when input information is information on the LF Vpp, the controller 100 calculates the LF Vpp from the information. Based on the measured LF Vpp or the calculated LF Vpp, the controller 100 calculates the impedance of the variable passive element of the second RF filter 63. The calculated impedance is output to the second RF filter 63 to control the second RF filter 63.

In addition, in the present embodiment, the controller 100 is provided in the etching apparatus 1, but may be arranged in any way. For example, the controller 100 may be provided separately from the etching apparatus 1 as a concentrating device. In addition, the controller 100 may be provided integrally with the second RF filter 63 or the variable passive element of the second RF filter 63, or may be separately provided after being divided into a plurality of the controllers.

According to the present embodiment, the impedance of the second RF filter 63 may be automatically adjusted, based on information output from the in-chamber sensor 300, the matching circuit sensor 301, the DC power sensor 302, and the filter path sensor 303.

In addition, in the present embodiment, the in-chamber sensor 300, the matching circuit sensor 301, the DC power sensor 302, and the filter path sensor 303 are provided, but types and the numbers of the sensors are not limited thereto. Any sensor that measures the LF Vpp or information on the LF Vpp may be used.

Alternatively, the same sensor may be installed at each portion (for example, sensors 300 to 303) to estimate or measure the information on the source RF power HF (for example, the load information or the HF Vpp). The information may be output to the controller 100, and may be used to control the impedance of RF filters 62 and 63. In addition, various sensors may be installed at any locations, depending on a measurement target. In addition, the information on the source RF power HF may be used to control the LF Vpp.

In addition, in the present embodiment, the in-chamber sensor 300, the matching circuit sensor 301, the DC power sensor 302, and the filter path sensor 303 are not essential, and any one of these may be omitted, or all of these may be omitted. When all of these sensors are omitted, an operator may manually set the impedance of the second RF filter 63. Alternatively, after setting the initial impedance, the operator may set the impedance in accordance with a time during which the controller 100 supplies the RF power.

### Another Embodiment

The etching apparatus 1 of the above-described embodiment may include a first variable passive element 64 and a second variable passive element 65 as illustrated in FIG. 13, instead of the DC power supply 60, the switching unit 61, the first RF filter 62, and the second RF filter 63. That is, the etching apparatus 1 does not include the DC power supply 60, and does not apply the negative DC voltage to the edge ring 14. The first variable passive element 64 and the second variable passive element 65 are arranged in this order from the edge ring 14 side. The second variable passive element 65 is connected to the ground potential. That is, the second variable passive element 65 is not connected to each of the source RF power supply 50 and the bias RF power supply 51.

In one example, at least one of the first variable passive element 64 and the second variable passive element 65 is configured to have the variable impedance. For example, the first variable passive element 64 and the second variable passive element 65 may be any of a coil (inductor) or a condenser (capacitor). In addition, without being limited to the coil or the condenser, any variable impedance element such as an element of diode may achieve the same function. The number and positions of the first variable passive element 64 and the second variable passive element 65 may be appropriately designed by those skilled in the art. In addition, the element itself does not need to be variable. For example, a plurality of elements having fixed impedance values may be provided, and the impedance may be varied by using a switching circuit to change a combination of the elements having the fixed values. In addition, each circuit configuration of the first variable passive element 64 and the second variable passive element 65 may be appropriately designed by those skilled in the art.

A relationship between the impedance of the first variable passive element 64 and the impedance of the second variable passive element 65 and the LF Vpp is the same as a relationship between the impedance of the second RF filter 63 and the LF Vpp illustrated in FIG. 6. That is, when the impedance of the variable passive elements 64 and 65 is increased, the LF Vpp is decreased. The LF Vpp may be controlled by adjusting the impedance of at least one of the first variable passive element 64 and the second variable passive element 65. In addition, when the impedance of the variable passive elements 64 and 65 is decreased depending on the circuit design of the variable passive elements 64 and 65 or the measurement location of the LF Vpp, the LF Vpp may be decreased in some cases. The impedance may be adjusted, depending on the circuit design of the variable passive elements 64 and 65 or the measurement location of the LF Vpp.

Here, the LF Vpp may vary due to factors other than variations in the DC voltage described above. For example, when an electromagnet is provided on the upper surface of the plasma processing chamber 10 and a magnetic field is formed in the processing space 10s, the LF Vpp may vary due to the magnetic field. Therefore, when the LF Vpp secondarily varies in this way, the LF Vpp may be controlled to fall within a constant or allowable range by adjusting the impedance of at least one of the variable passive elements 64 and 65 as in the present embodiment.

For example, in some cases, any control target value of the LF Vpp may be set, and an adjustment function related to a process such as the RF power may not be varied. For example, when the RF power is adjusted, the adjustment of the RF power may have an influence on heat input to the wafer, or may have an influence on process performance. In this case, the LF Vpp may be controlled to a control target value by adjusting the impedance of at least one of the variable passive elements 64 and 65 as in the present embodiment.

In addition, the LF Vpp may be controlled by adjusting the impedance of at least one of the variable passive elements 64 and 65. Therefore, the voltage of the edge ring 14 which is the connection point of the variable passive elements 64 and 65 may be adjusted. As a result, the consumption amount of the edge ring 14 may be controlled by the voltage.

In addition, in the present embodiment, although the LF Vpp is controlled by adjusting the impedance of at least one of the variable passive elements 64 and 65, the tilt angle may also be controlled. The method for controlling the tilt angle by adjusting the impedance of the variable passive elements 64 and 65 is similar to the method for controlling the tilt angle by adjusting the impedance of the second RF filter 63 described above.

In addition, in the present embodiment, although the variable passive elements 64 and 65 control the LF Vpp by adjusting the impedance, the variable passive elements 64 and 65 may be configured to control the HF Vpp. Here, the HF Vpp may vary due to various factors. For example, when a pulse power supply configured to apply a pulse voltage other than the bias RF power LF to the lower electrode 12 is used instead of the bias RF power supply 51, the HF Vpp is likely to vary. In this case, the HF Vpp may be controlled to fall within a constant or allowable range by adjusting the impedance of at least one of the variable passive elements 64 and 65.

In addition, in the present embodiment, the edge ring 14 and the variable passive elements 64 and 65 may be electrically connected. For example, the edge ring 14 and the variable passive elements 64 and 65 may be connected by non-contact or capacitive coupling. Alternatively, for example, as illustrated in FIG. 14, the edge ring 14 and the variable passive elements 64 and 65 may be electrically directly connected by the connection portion 200. The configuration of the connection portion 200 is the same as the configuration of the connection portion 200 illustrated in FIG. 11. In addition, when the edge ring 14 and the variable passive elements 64 and 65 are electrically directly connected, even when the frequency of the bias RF power LF is low, an advantageous effect of maintaining controllability of LF Vpp may be achieved.

In addition, in the present embodiment, although the variable passive elements 64 and 65 are electrically connected to the edge ring 14, the connection location of the variable passive elements 64 and 65 is not limited thereto. For example, the variable passive elements 64 and 65 may be electrically connected to the lower electrode 12, a conductive component forming the lower electrode 12, a transmission path for the RF power, a circuit inside the matching circuit 52, and a pulse power supply or the like used instead of the source RF power supply 50 or the bias RF power supply 51.

In addition, in the present embodiment, although two variable passive elements 64 and 65 are provided, the number of the variable passive elements is not limited thereto. For example, only one of the variable passive elements 64 and 65 may be provided. When the second variable passive element 65 is omitted, the first variable passive element 64 is connected to ground potential. In addition, when the first variable passive element 64 is omitted, the second variable passive element 65 is connected to ground potential. In this case, the impedance of the second variable passive element 65 is configured to be variable. However, a function or a circuit provided when the impedance of the first variable passive element 64 is fixed may be incorporated into the second variable passive element 65.

### Another Embodiment

In the above-described embodiment, the LF Vpp is controlled by adjusting the impedance of the second RF filter 63, and the LF Vpp or the HF Vpp is controlled by adjusting the impedance of at least one of the variable passive elements 64 and 65, but the control target is not limited to the Vpp. For example, the power or the current may be controlled as the control target.

### Another Embodiment

Although the etching apparatus 1 of the above-described embodiment is a capacitively coupled etching apparatus, the etching apparatus to which the present disclosure is applied is not limited thereto. For example, the etching apparatus may be an inductively coupled etching apparatus.

The disclosed embodiments should be considered as illustrative and not restrictive in all respects. The above-described embodiments may be omitted, substituted, or modified in various forms without departing from the scope and the concept of the appended claims. For example, configuration elements of the above-described embodiments may be optionally combined. From the optionally combined elements, the operations and the advantageous effects of the respective configuration elements related to the combination are naturally achieved, and from the description of the present specification, other operations and other advantageous effects are clearly achieved by those skilled in the art.

In addition, the advantageous effects described in the present specification are merely illustrative or exemplary, and are not limited. That is, the technology according to the present disclosure may achieve other advantageous effects that are obvious to those skilled in the art from the description of the present specification, together with the above-described advantageous effects or instead of the above-described advantageous effects.

In addition, the following configuration examples also fall within the technical scope of the present disclosure.

(1)

A plasma processing apparatus comprising:
a plasma processing chamber;
a substrate support arranged inside the plasma processing chamber, the substrate support including a lower electrode, an electrostatic chuck, and an edge ring disposed to surround a substrate mounted on the electrostatic chuck;
an upper electrode arranged on an upper side of the substrate support;
a source RF power supply configured to supply source RF power to the upper electrode or the lower electrode to generate plasma from a gas inside the plasma processing chamber;
a bias power supply configured to supply bias power to the lower electrode;
a DC power supply configured to apply a negative DC voltage to the edge ring;
an RF filter electrically connected between the edge ring and the DC power supply, and including at least one variable passive element; and
a controller configured to control the DC power supply and the variable passive element to adjust an incident angle of ions in the plasma with respect to an edge region of a substrate mounted on the electrostatic chuck, and configured to control a voltage of the bias power within a permissible range.
   (2)

The plasma processing apparatus of (1), further comprising:
at least one conductor configured to be in contact with the edge ring,
wherein the DC power supply is configured to apply a negative DC voltage to the edge ring via the at least one conductor, and the RF filter is electrically connected between the at least one conductor and the DC power supply.
   (3)

The plasma processing apparatus of (1) or (2), wherein the controller is configured to simultaneously adjust the DC voltage of the DC power supply and the impedance of the variable passive element.

(4)

The plasma processing apparatus of (1) or (2), wherein the controller is configured to individually adjust the DC voltage of the DC power supply and the impedance of the variable passive element.

(5)

The plasma processing apparatus of any one of (1) to (4), wherein the controller is configured to control the incident angle of the ions by adjusting the DC voltage of the DC power supply.

(6)

The plasma processing apparatus of any one of (1) to (5), wherein the controller is configured to control the voltage of the bias power within the permissible range by adjusting the increase or decrease in impedance of the variable passive element.

(7)

The plasma processing apparatus of any one of (1) to (6), further comprising:
a sensor for configured to measure the voltage of the bias power or information related to the voltage of the bias power,
wherein the controller controls the variable passive element based on the measurement result of the sensor.
   (8)

A plasma processing apparatus comprising:
a plasma processing chamber;
a substrate support arranged inside the plasma processing chamber, the substrate support including an electrostatic chuck and an edge ring disposed to surround a substrate mounted on the electrostatic chuck;
an RF power supply configured to generate RF power for plasma generation from a gas inside the plasma processing chamber;
at least one variable passive element; and
a controller configured to control a voltage of the RF power by controlling the variable passive element.
   (9)

The plasma processing apparatus of (8), wherein the at least one variable passive element is electrically coupled to the edge ring.

(10)

The plasma processing apparatus of (9), further comprising:
at least one conductor in contact with the edge ring,
wherein the at least one variable passive element is electrically coupled to the edge ring via the at least one conductor.
   (11)

An etching method using a plasma processing apparatus, the plasma processing apparatus including a plasma processing chamber, a substrate support disposed inside the plasma processing chamber, the substrate support including an electrostatic chuck and an edge ring arranged to surround a substrate mounted on the electrostatic chuck, an RF power supply configured to generate RF power for plasma generation from a gas inside the plasma processing chamber, and at least one variable passive element, the etching method comprising:
(a) mounting the substrate on the electrostatic chuck;
(b) generating plasma from the gas inside the plasma processing chamber by using the RF power;
(c) etching the substrate using the generated plasma; and
(d) controlling a voltage of the RF power by controlling the at least one variable passive element.

1. A plasma processing apparatus comprising:
a plasma processing chamber;
a substrate support arranged inside the plasma processing chamber, the substrate support including a lower electrode, an electrostatic chuck, and an edge ring disposed to surround a substrate mounted on the electrostatic chuck;
an upper electrode arranged on an upper side of the substrate support;
a source RF power supply configured to supply source RF power to the upper electrode or the lower electrode to generate plasma from a gas inside the plasma processing chamber;
a bias power supply configured to supply bias power to the lower electrode;
a DC power supply configured to apply a negative DC voltage to the edge ring;
an RF filter electrically connected between the edge ring and the DC power supply, and including at least one variable passive element; and
a controller configured to control the DC power supply and the variable passive element to adjust an incident angle of ions in the plasma with respect to an edge region of a substrate mounted on the electrostatic chuck, and configured to control a voltage of the bias power within a permissible range.

2. The plasma processing apparatus of claim 1, further comprising:
at least one conductor configured to be in contact with the edge ring,
wherein the DC power supply is configured to apply a negative DC voltage to the edge ring via the at least one conductor, and the RF filter is electrically connected between the at least one conductor and the DC power supply.

3. The plasma processing apparatus of claim 1, wherein the controller is configured to simultaneously adjust the DC voltage of the DC power supply and the impedance of the variable passive element.

4. The plasma processing apparatus of claim 1, wherein the controller is configured to individually adjust the DC voltage of the DC power supply and the impedance of the variable passive element.

5. The plasma processing apparatus of claim 1, wherein the controller is configured to control the incident angle of the ions by adjusting the DC voltage of the DC power supply.

6. The plasma processing apparatus of claim 1, wherein the controller is configured to control the voltage of the bias power within the permissible range by adjusting the increase or decrease in impedance of the variable passive element.

7. The plasma processing apparatus of claim 1, further comprising:
a sensor for configured to measure the voltage of the bias power or information related to the voltage of the bias power,
wherein the controller controls the variable passive element based on the measurement result of the sensor.

8. A plasma processing apparatus comprising:
a plasma processing chamber;
a substrate support arranged inside the plasma processing chamber, the substrate support including an electrostatic chuck and an edge ring disposed to surround a substrate mounted on the electrostatic chuck;
an RF power supply configured to generate RF power for plasma generation from a gas inside the plasma processing chamber;
at least one variable passive element; and
a controller configured to control a voltage of the RF power by controlling the variable passive element.

9. The plasma processing apparatus of claim 8, wherein the at least one variable passive element is electrically coupled to the edge ring.

10. The plasma processing apparatus of claim 9, further comprising:
at least one conductor in contact with the edge ring,
wherein the at least one variable passive element is electrically coupled to the edge ring via the at least one conductor.

11. An etching method using a plasma processing apparatus, the plasma processing apparatus including a plasma processing chamber, a substrate support disposed inside the plasma processing chamber, the substrate support including an electrostatic chuck and an edge ring arranged to surround a substrate mounted on the electrostatic chuck, an RF power supply configured to generate RF power for plasma generation from a gas inside the plasma processing chamber, and at least one variable passive element, the etching method comprising:
(a) mounting the substrate on the electrostatic chuck;
(b) generating plasma from the gas inside the plasma processing chamber by using the RF power;
(c) etching the substrate using the generated plasma; and
(d) controlling a voltage of the RF power by controlling the at least one variable passive element.
